(19) United States
(12) Patent Application Publication
(10) Pub. No.: US 2007/0034949 A1
(43) Pub. Date: Feb. 15, 2007

(54) Semiconductor device having multiple source/drain extension implant portions and a method of manufacture therefor

(75) Inventor: James D. Bernstein, Plano, TX (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/201,925

(22) Filed: Aug. 11, 2005

(51) Int. Cl. H01L 29/76; H01L 21/336

(52) U.S. Cl. 257/346; 257/387; 438/307

(57) ABSTRACT

The present invention provides a semiconductor device, a method for manufacturing therefore, and an integrated circuit including the same. The semiconductor device, in one advantageous embodiment, includes a gate structure (230) located over a substrate (210), and a source/drain region (250) located within the substrate (210) and proximate the gate structure (230). The source/drain region (250), in this advantageous embodiment, may include a first source/drain extension implant portion (260) located within the substrate (210), the first source/drain extension implant portion (260) comprising a dopant and having a vertical dimension into the substrate (210) and a lateral dimension toward or under the gate structure (230), as well as a second source/drain extension implant portion (265) located within the substrate (210), the second source/drain extension implant portion (265) comprising a different dopant and having a lesser vertical dimension into the substrate (210) and a greater lateral dimension toward or under the gate structure (230).

### TECHNICAL FIELD OF THE INVENTION

The present invention is directed, in general, to a semiconductor device and, more specifically, to a semiconductor device having multiple source/drain extension implant portions, a method of manufacture therefore, and an integrated circuit including the same.

### BACKGROUND OF THE INVENTION

Advanced integrated circuit design requires precise control of beam incidence angle. While a number of different types of beam incidence angle error exist, three of the more common types are cone angle error, beam steering error and parallelism error across the wafer. Cone angle error is typically a result of cone angle effects caused by the geometry of the wafer scanning system. Cone angle error causes within wafer variation. For example the beam angle error may be about −x degrees at one edge of the wafer, be approximately zero degrees as the center of the wafer, and be about +x degrees at the opposing edge of the wafer.

Steering error, on the other hand, tends to be a fixed error across the wafer that is introduced while tuning the beam between lots, implant batches, or whenever the tuning may occur. The parallelism error, for whatever reason, leads to random beam incidence angle errors across the width of the wafer. This error is particularly difficult to correct as a result of its random nature.

Unfortunately, without precise control of beam incidence angle, various different problems degrade the transistors of the integrated circuit. As an example, transistor asymmetry, variation, and depressed yield often result due to beam incidence angle error. The beam incidence angle error also typically leads to gate shadowing and an asymmetric dopant distribution, both of which are undesirable.

Turning to FIG. 1A, illustrated is an example of gate shadowing on a transistor device 100. The transistor device 100 illustrated in FIG. 1A includes a gate structure 120, having a height (h), located over a substrate 110. The transistor device 100 illustrated in FIG. 1A is being subjected to a focused implant process 130 to form implant regions 140. As is illustrated, the combination of the focused implant beam incidence angle (θ) and gate structure 120 height (h) causes the implant regions 140 located within the substrate 110 not be placed equidistance from the gate structure 120. For example, one of the implant regions 140 is located a distance (d) from the sidewall of the gate structure 120, where the other implant region 140 is located adjacent the sidewall of the gate structure 120. While the distance (d) can be estimated using the equation d=h tan (θ), it nevertheless creates an undoped/underdoped region defined by the distance (d) that often tends to cause serious operational problems for the transistor device 100.

Turning now briefly to Prior Art FIG. 1B, illustrated is another source of transistor asymmetry. As is illustrated in FIG. 1B, transistor asymmetry may also be caused by gate structure 120 profile non-uniformities. For example, wherein one side of the gate structure 120 profile is different from the other side of the gate structure 120 profile, such as shown in FIG. 1B, transistor asymmetry may result. The effects of the non-uniform gate structure 120 profile can also cause serious operational problems for the transistor device 100.

Accordingly, what is needed in the art is a method for implanting dopants within a substrate that does not experience the drawbacks of the prior art methods and devices.

### SUMMARY OF THE INVENTION

To address the above-discussed deficiencies of the prior art, the present invention provides a semiconductor device, a method of manufacture therefore, and an integrated circuit including the same. The semiconductor device, in one advantageous embodiment, includes a gate structure located over a substrate, and a source/drain region located within the substrate and proximate the gate structure. The source/drain region, in this advantageous embodiment, may include a first source/drain extension implant portion located within the substrate, the first source/drain extension implant portion comprising a dopant and having a vertical dimension into the substrate and a lateral dimension toward or under the gate structure, and a second source/drain extension implant portion located within the substrate, the second source/drain extension implant portion comprising a different dopant and having a lesser vertical dimension into the substrate and a greater lateral dimension toward or under the gate structure.

In addition to the semiconductor device, the present invention provides a method for manufacturing the semiconductor device, which without limitation includes forming the aforementioned semiconductor device. The present invention, in another embodiment, provides the integrated circuit. The integrated circuit, among other elements, may include: (1) semiconductor devices located over or in a substrate, the semiconductor devices including features similar to the semiconductor device disclosed above, and (2) dielectric layers located over the semiconductor devices, the dielectric layers having interconnects therein for forming an operational integrated circuit.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGS. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIGS. 1A & 1B illustrates cross-sectional views of prior art semiconductor devices showing at least two causes of transistor asymmetry;

FIG. 2 illustrates a cross-sectional view of one embodiment of a semiconductor device constructed according to the principles of the present invention;

FIG. 3 illustrates a cross-sectional view of a partially completed semiconductor device;

FIG. 4 illustrates a cross-sectional view of the partially completed semiconductor device illustrated in FIG. 3 after formation of a conventional gate structure over the substrate;

FIG. 5 illustrates a cross-sectional view of the partially completed semiconductor device illustrated in FIG. 4 after formation of first source/drain extension implant portions and second source/drain extension implant portions within the substrate, using a first dopant and a second different dopant, respectively;

FIG. 6 illustrates a cross-sectional view of the partially completed semiconductor device illustrated in FIG. 5 after annealing the first and second source/drain extension implant portions to form completed first and second source/drain extension implant portions;

FIG. 7 illustrates a cross-sectional view of the partially completed semiconductor device illustrated in FIG. 6 after formation of gate sidewall spacers and formation of source/drain contact implants within the substrate; and

FIG. 8 illustrates a cross-sectional view of a conventional integrated circuit (IC) incorporating semiconductor devices constructed according to the principles of the present invention.

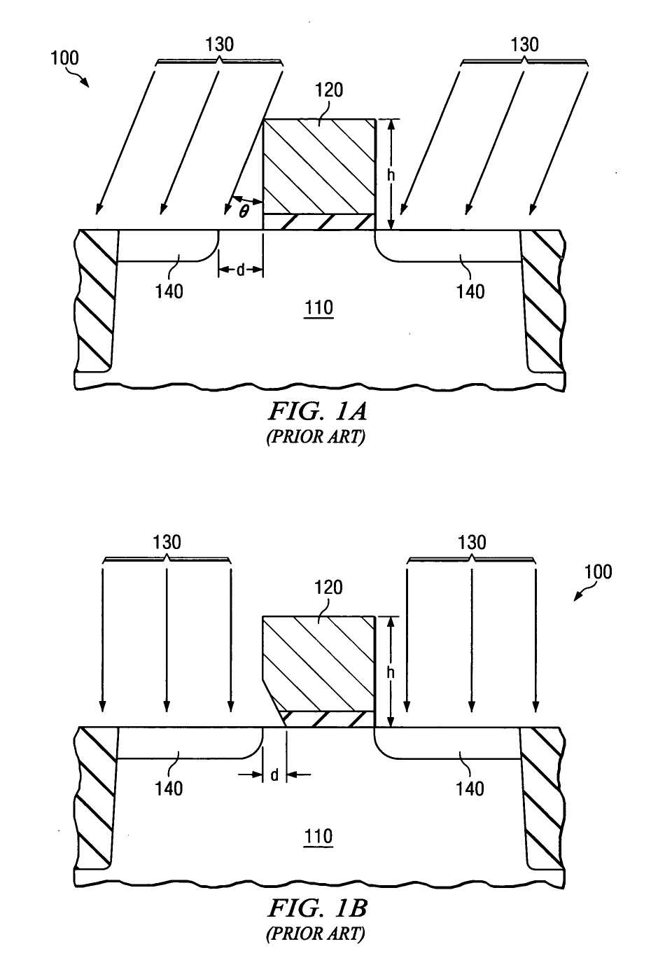

### DETAILED DESCRIPTION

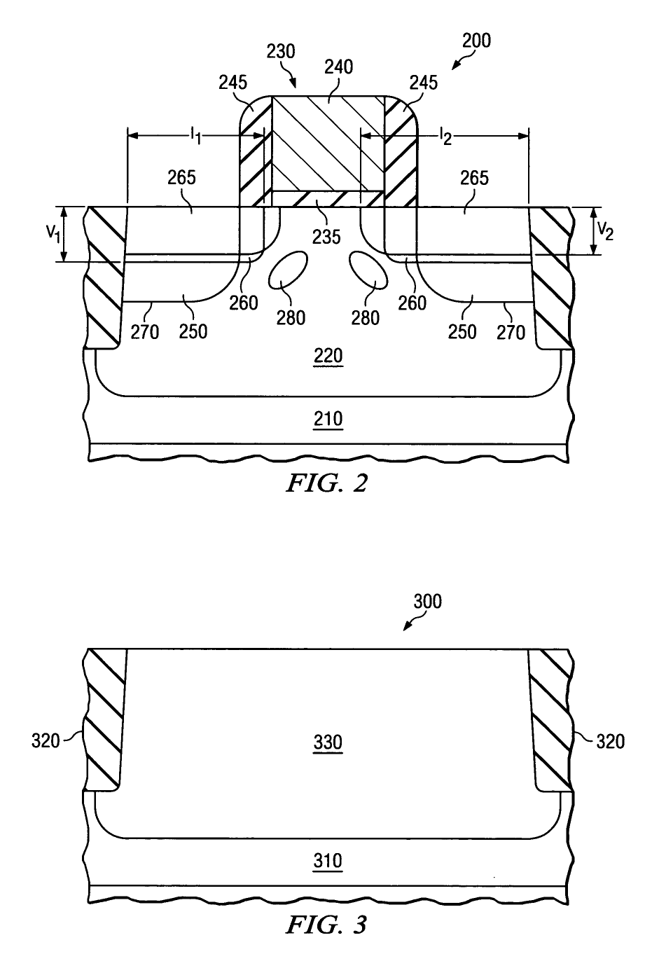

Referring initially to FIG. 2, illustrated is a cross-sectional view of one embodiment of a semiconductor device 200 constructed according to the principles of the present invention. In the embodiment illustrated in FIG. 2, the semiconductor device 200 includes a substrate 210. Located within the substrate 210 in the embodiment of FIG. 2 is a well region 220. Additionally, located over the substrate 210 and well region 220 is a gate structure 230.

The gate structure 230 illustrated in FIG. 2 includes a gate dielectric 235 located over the substrate 210, as well as a gate electrode 240 located over the gate dielectric 235. Flanking both sides of the gate electrode 240 and gate dielectric 235 are gate sidewall spacers 245. Each of the features of the gate structure 230 are conventional.

The semiconductor device 200 illustrated in FIG. 2 further includes source/drain regions 250 located within the substrate 210. Unique to the present invention, the source/drain regions 250 may include first source/drain extension implant portions 260 and second source/drain extension implant portions 265. In the illustrative embodiment of FIG. 2, the first source/drain extension implant portions 260 comprise a first dopant, and have a vertical dimension (v₁) into the substrate 210 and a lateral dimension (l₁) toward or under the gate structure 230. In contrast, the second source/drain extension implant portions 265 comprise a second different dopant, and have a lesser vertical dimension (v₂) into the substrate 210 and a greater lateral dimension (l₂) toward or under the gate structure 230.

The first and second source/drain extension implant portions 260, 265 may also differ from one another in other ways. For instance, as illustrated in FIG. 2, the first source/drain extension implant portions 260 may not extend under the gate electrode 240 portion of the gate structure 230, while the second source/drain extension implant portions 265 generally do extend under the gate electrode 240 portion of the gate structure 230. Additionally, the first and second source/drain extension implant portions 260, 265, may be implanted using different doses, and possibly energies, thus the first and second source/drain extension implant portions 260, 265 may have different peak dopant concentrations. For example, the first dopant in the first source/drain extension implant portions 260 may have, among others, a peak concentration ranging from about 1E19 atoms/cm³ to about 1E22 atoms/cm³, and the second different dopant in the second source/drain extension implant portions 265 may have, among others, a peak concentration ranging from about 5E17 atoms/cm ³ to about 2E22 atoms/cm ³.

The differences in the positioning of the first and second source/drain extension implant portions 260, 265, is at least partially related to the dopants that each comprises. For example, in one exemplary embodiment of the present invention, the diffusivity of the second different dopant is greater than the diffusivity of the first dopant. Accordingly, when the first and second dopants are implanted into the substrate 210 to form the first and second source/drain extension implant portions 260, 265, respectively, and thereafter are subjected to a thermal anneal, the second dopant will diffuse a greater distance than the first resulting in l₂>l₁. This occurs because the as-implanted (un-annealed) lateral profile is to first order defined by the gate or other structure in a self-aligned implant process. A second order effect that contributes to l₂>l₁ is that a smaller atom such as phosphorus which may be chosen as a second dopant will have a larger lateral straggle than arsenic which may be chosen as a first dopant. Since the as-implanted lateral dimension of the second dopant is approximately equal to or greater than the first, it will generally diffuse further than the first dopant when the diffusivity of the second dopant is greater than that of the first. This generally has a larger effect than concentration gradient effects in this application. The second dopant may be prevented from diffusing beyond the first dopant such that v₂<v₁, by using a lower implant energy for the second dopant so that the as-implanted profile of the second dopant is sufficiently shallower than the first so that after thermal processing the diffusion of the second dopant will not overrun the first dopant in the vertical dimension.

A number of different dopant combinations having different diffusivities may be used to achieve the aforementioned positioning. For example, when the semiconductor device 200 comprises an NMOS device, the first dopant might be arsenic and the second different dopant might be phosphorous, among others. Similarly, when the semiconductor device 200 comprises a PMOS device, the first dopant might be indium and the second different dopant might be boron. These are but a few of the different combinations of dopants that might be used for NMOS and PMOS devices to achieve the aforementioned positioning of the first and second source/drain extension implant portions 260, 265.

Referring back to FIG. 2, the source/drain regions 250 further include source/drain contact implants 270. The source/drain contact implants 270, which are often referred to in the industry as highly doped source/drain implants or deep source/drain implants, are generally aligned to the sidewall spacers 245, and extend into the substrate 210 vertically deeper than the first and second source/drain extension implant portions 260, 265. Nevertheless, other embodiments might exist wherein the source/drain contact implants 270 extend into the substrate about the same vertical distance as the first source/drain extension implant portions 260.

The source/drain contact implants 270 may comprise the first dopant, the second different dopant or another dopant while staying within the purview of the present invention. However, an exemplary embodiment of the present invention has the source/drain contact implants 270 comprising the first dopant, and moreover, having a peak dopant concentration ranging from about 1E19 atoms/cm³ to about 1E22 atoms/cm³.

The unique positioning of the source/drain implant regions 250, and particularly the first and second source/drain extension implant portions 260, 265, provide a number of benefits. For instance, as the second source/drain extension implant portions 265 extend at least a small distance under the gate electrode 240 portion of the gate structure 230, the transistor asymmetry problems are greatly reduced, if not eliminated in certain circumstances. In the case of more severe angle error, the lateral dimension of the undoped or partially doped area is reduced by the lateral diffusion of the second dopant. It may not extend under the gate for severe angle variations on the shadowed side but the lateral diffusion will still provide a large improvement compared to a conventional process. This also helps improve any parametric variation that may be present. Additionally, the benefits are easily attained using processes and techniques that already exist in the industry. In addition to reduced parametric variation and improved yield, benefits can include a more graded dopant profile which can reduce the electric field and reduce channel hot-carrier degradation, improving reliability.

In addition to the various different doped regions in the substrate 210, the semiconductor device 200 may further include conventional halo/pocket implants 280 within the substrate 210. The conventional halo/pocket implants, as would be expected by one skilled in the art, are doped with an opposite dopant as the first and second source/drain extension implant portions 260, 265, and the source/drain contact implants 270.

Turning now to FIGS. 3-7, illustrated are cross-sectional views of detailed manufacturing steps instructing how one might, in an advantageous embodiment, manufacture a semiconductor device similar to the semiconductor device 200 depicted in FIG. 2. FIG. 3 illustrates a cross-sectional view of a partially completed semiconductor device 300. The partially completed semiconductor device 300 of FIG. 3 includes a substrate 310. The substrate 310 may, in an exemplary embodiment, be any layer located in the partially completed semiconductor device 300, including a wafer itself or a layer located above the wafer (e.g., epitaxial layer). In the embodiment illustrated in FIG. 3, the substrate 310 is a p-type semiconductor substrate; however, one skilled in the art understands that the substrate 310 could be an n-type substrate without departing from the scope of the present invention. In such a case, each of the dopant types described throughout the remainder of this document might be reversed. For clarity, no further reference to this opposite scheme will be discussed.

Located within the substrate 310 in the embodiment shown in FIG. 3 are isolation regions 320, such as shallow trench isolation regions. The isolation regions 320 isolate the semiconductor device 300 from other devices located proximate thereto. As those skilled in the art understand the various steps used to form these conventional isolation regions 320, no further detail will be given.

In the illustrative embodiment of FIG. 3, also formed within the substrate 310 is a well region 330. The well region 330 in the embodiment shown and discussed with respect to FIGS. 3-7 contains a p-type dopant, thus making the transistor an n-type metal oxide semiconductor (NMOS) device. For example, the well region 330 would likely be doped with a p-type dopant dose ranging from about 1E13 atoms/cm² to about 1E14 atoms/cm² and at an energy ranging from about 100 keV to about 500 keV. What generally results is the well region 330 having a peak dopant concentration ranging from about 5E17 atoms/cm³ to about 1E19 atoms/cm³. It goes without saying that the well region 330 could contain an n-type dopant, thus making the transistor a PMOS device, without departing from the scope of the present invention. Nevertheless, for consistency the remainder of the document will be discussed as an NMOS device.

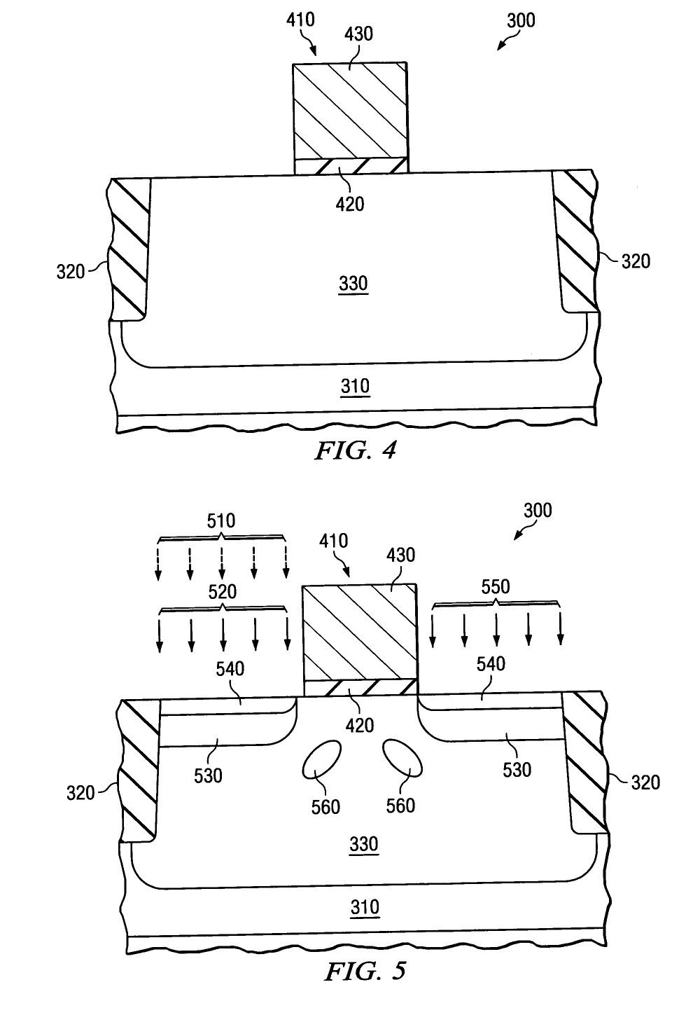

Turning now to FIG. 4, illustrated is a cross-sectional view of the partially completed semiconductor device 300 illustrated in FIG. 3 after formation of a conventional gate structure 410 over the substrate 310. As is illustrated in FIG. 4, the gate structure 410 includes a gate dielectric 420 and a gate electrode 430. As the gate structure 410 is conventional, those skilled in the art understand the standard steps used for its manufacture, including blanket depositing both a gate dielectric layer and a gate electrode layer and subsequently using photolithography to define the gate structure 410. The gate dielectric 420, among others, may comprise a high-k dielectric without departing from the scope of the present invention. Similarly, the gate electrode 430, among others, may comprise a metal gate material or polysilicon, without departing from the scope present invention.

Turning now to FIG. 5, illustrated is a cross-sectional view of the partially completed semiconductor device 300 illustrated in FIG. 4 after formation of first source/drain extension implant portions 530 and second source/drain extension implant portions 540 within the substrate 310, using a first dopant 510 and a second different dopant 520, respectively. The FIGURE indicates dopant location prior to dopant diffusion. The first source/drain extension implant portions 530 may be formed using conventional processes, however, unique parameters. For instance, the first source/drain extension implant portions 530 would likely be doped with a first dopant 510 dose ranging from about 1E14 atoms/cm² to about 5E15 atoms/cm² and at an energy ranging from about 0.2 keV to about 10 keV. Such parameters should, in an exemplary embodiment, cause the first source/drain extension implant portions 530 to extend into the substrate 310 a distance ranging from about 5 nm to about 200 nm (approximate junction depth).

While the first dopant 510 used in the embodiment of FIG. 5 to form the first source/drain extension implant portions 530 may vary, it should be a dopant having a reduced diffusivity. For example, in those embodiments wherein the semiconductor device 300 is an NMOS device, the first dopant 510 could comprise an n-type dopant, such as arsenic, which has a reduced diffusivity. In those embodiments wherein the semiconductor device 300 is a PMOS device, the first dopant 510 could comprise a p-type dopant, such as indium, which also has a reduced diffusivity. Other n-type and p-type first dopants 510 having the reduced diffusivity may also exist, and thus are within the scope of the present invention.

The second source/drain extension implant portions 540 may also be formed using conventional processes, however, unique parameters. For instance, the second source/drain extension implant portions 540 would likely be doped with a second different dopant 520 dose ranging from about 1E12 atoms/cm² to about 2E15 atoms/cm² and at an energy ranging from about 0.0 keV to about 5 keV. Such parameters should, in an exemplary embodiment, cause the second source/drain extension implant portions 540 to have a shallower depth into the substrate 310 than the first source/drain extension implant portions 530. For instance, the second source/drain extension implant portions 540 should only extend into the substrate 310 a distance ranging from about 1 nm to about 50 nm, among others.

While the second different dopant 520 used in the embodiment of FIG. 5 to form the second source/drain extension implant portions 540 may vary, it should be a dopant having an increased diffusivity, at least as compared to the first dopant 510. For example, in those embodiments wherein the semiconductor device 300 is an NMOS device, the second dopant 520 could comprise an n-type dopant, such as phosphorous, which has a greater diffusivity than for example arsenic. In those embodiments wherein the semiconductor device 300 is a PMOS device, the second dopant 520 could comprise a p-type dopant, such as boron, which has a greater diffusivity than for example indium. Other n-type and p-type second different dopants 520 having the greater diffusivity may also exist, and thus are within the scope of the present invention.

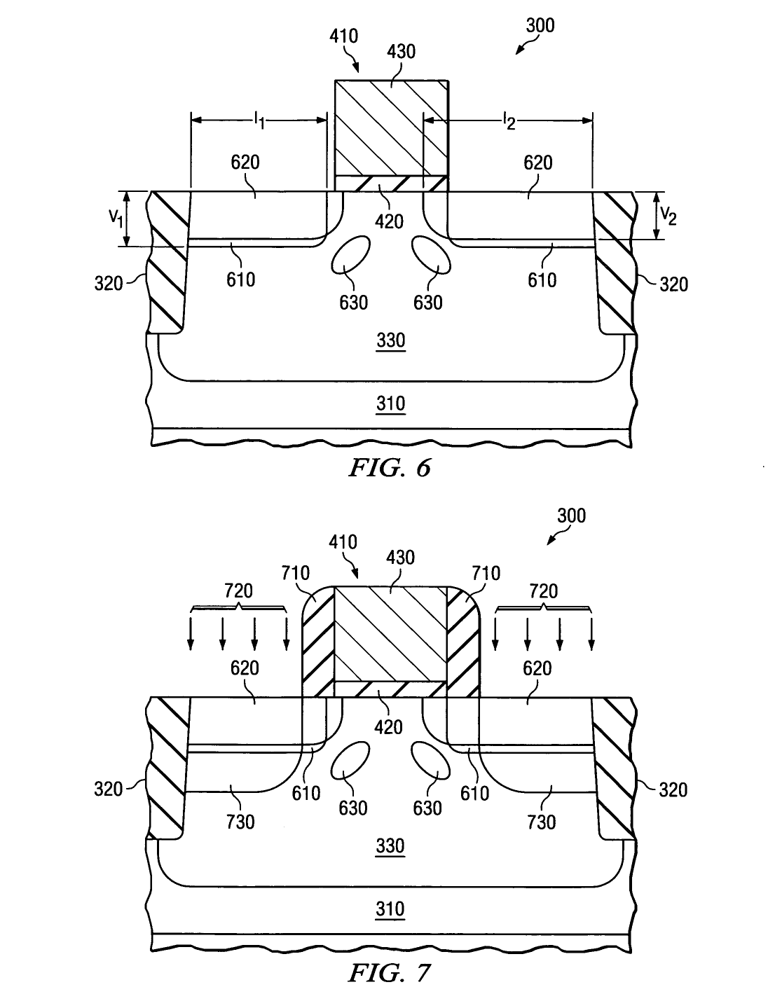

It should be noted that the parameters (e.g., dopant types, dopant doses, dopant energies, etc.) used to form the first and second source/drain extension implant portions 530, 540 are generally driven by the desire to have the second source/drain extension implant portions 540 (FIG. 6) not extend into the substrate 310 in the longitudinal direction past the first source/drain extension implant portions 530. By not extending into the substrate 310 further than the first source/drain extension implant portions 530, the second source/drain extension implant portions 540 do not affect the junction between the first source/drain extension implant portions 530 and the well region 330.

It should also be noted that there is no particular order in which the first and second source/drain extension implant portions 530, 540 should be formed. Accordingly, while the embodiment discussed above references the formation of the first source/drain extension implant portions 530 first and the formation of the second source/drain extension implant portions 540 second, the inverse may also hold true.

Also illustrated in FIG. 5 is the formation of halo/pocket implants 560 within the substrate using the dopant 550. As those skilled in the art understand, the halo/pocket implants 560 should have an opposite dopant type to the first source/drain extension implant portions 530 and the second source/drain extension implant portions 540. The halo/pocket implants 560 are conventionally formed, thus no further detail is warranted.

Turning now to FIG. 6, illustrated is a cross-sectional view of the partially completed semiconductor device 300 illustrated in FIG. 5 after annealing the first and second source/drain extension implant portions 530, 540, to form completed first and second source/drain extension implant portions 610, 620. The anneal, in an exemplary embodiment, may be conducted at a temperature ranging from about 550° C. to about 1150° C. for a time period ranging from about 1 micro-second to about 12 hours. Other temperatures and time may, nevertheless, also be used.

It should be noted that this anneal may be broken into more than one anneal without departing from the scope of the present invention. For instance, the anneal could be broken into two different anneals that are conducted directly after forming each of the first and second source/drain extension implant portions 530, 540. Care, however, would need to be taken to assure the appropriate final positioning of the second source/drain extension implant portions 620, as related to the first source/drain extension implant portions 610. The first implant defines and forms the longitudinal junction and the second implant defines and forms the lateral junction.

What results, as is illustrated in FIG. 6, is that the first source/drain extension implant portions. 610 do not extend under the gate electrode 430 portion of the gate structure 410 as far as the second source/drain extension implant portions 620 extend under the gate electrode 430 portion of the gate structure 410. This unique attribute, as previously indicated, provides improved transistor asymmetry and improved parametric variation. What additionally results is that the first source/drain extension implant portions 610 have a vertical dimension (v₁) into the substrate 310 and a lateral dimension (l₁) toward or under the gate structure 410, and the second source/drain extension implant portions 620 have a lesser vertical dimension (v₂) into the substrate 310 and a greater lateral dimension (l₂) toward or under the gate structure 410. What further may result is that the first dopant in the first source/drain extension implant portions 610 may have, among others, a peak concentration ranging from about 1E19 atoms/cm³ to about 1E22 atoms/cm³, and the second different dopant in the second source/drain extension implant portions 620 may have, among others, a peak concentration ranging from about 5E17 atoms/cm³ to about 2E22 atoms/cm ³.

It should also be noted that during the annealing of the first and second source/drain extension implant portions 530, 540, to form completed first and second source/drain extension implant portions 610, 620, the halo/pocket implants 560 are annealed to form completed halo/pocket implants 630. The resulting completed halo/pocket implants 630 are illustrated in FIG. 6.

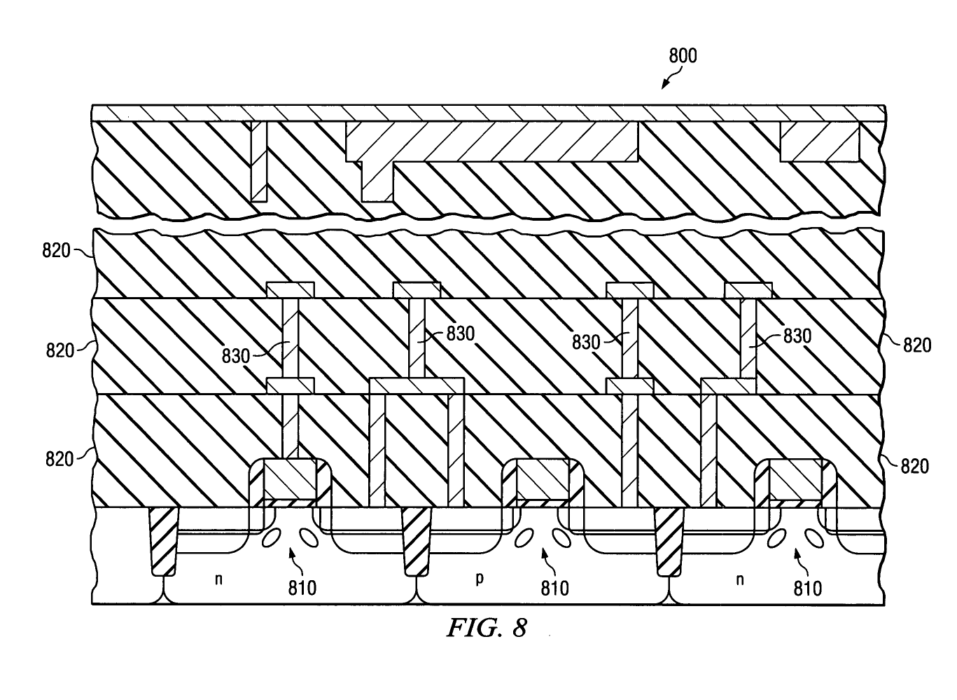

Turning now to FIG. 7, illustrated is a cross-sectional view of the partially completed semiconductor device 300 illustrated in FIG. 6 after formation of gate sidewall spacers 710 and formation of source/drain contact implants 720 within the substrate 310. Those skilled in the art understand the conventional processes that might be used to form the gate sidewall spacers 710. Thus, limited discussion is warranted.

The source/drain contact implants 730 are conventionally formed using the dopant 720 and generally have a peak dopant concentration ranging from about 1E18 atoms/cm³ to about 1E22 atoms/cm³. Also, the source/drain contact implants 730 should typically have a dopant type opposite to that of the well region 330 they are located within. Accordingly, in the illustrative embodiment shown in FIG. 7, the source/drain contact implants 730 are doped with an n-type dopant. For example, in one embodiment the source/drain contact implants 730 may comprise the same dopant as the first dopant 510, the second different dopant 520, or another suitable dopant. Nevertheless, in the embodiment of FIG. 7 the source/drain contact implants 730 comprise a dopant similar to the first dopant 510. After forming the source/drain contact implants 730, the manufacturing process would continue in a conventional manner, ultimately resulting in a device similar to the semiconductor device 200 illustrated in FIG. 2.

Referring finally to FIG. 8, illustrated is a cross-sectional view of a conventional integrated circuit (IC) 800 incorporating semiconductor devices 810 constructed according to the principles of the present invention. The IC 800 may include devices, such as transistors used to form CMOS devices, BiCMOS devices, Bipolar devices, or other types of devices. The IC 800 may further include passive devices, such as inductors or resistors, or it may also include optical devices or optoelectronic devices. Those skilled in the art are familiar with these various types of devices and their manufacture. In the particular embodiment illustrated in FIG. 8, the IC 800 includes the semiconductor devices 810 having dielectric layers 820 located thereover. Additionally, interconnect structures 830 are located within the dielectric layers 820 to interconnect various devices, thus, forming the operational integrated circuit 800.

Although the present invention has been described in detail, those skilled in the art should understand that they can make various changes, substitutions and alterations herein without departing from the spirit and scope of the invention in its broadest form.

What is claimed is:

1. A semiconductor device, comprising:
a gate structure located over a substrate; and
a source/drain region located within the substrate and proximate the gate structure, the source/drain region including;
a first source/drain extension implant portion located within the substrate, the first source/drain extension implant portion comprising a dopant and having a vertical dimension into the substrate and a lateral dimension toward or under the gate structure; and
a second source/drain extension implant portion located within the substrate, the second source/drain extension implant portion comprising a different dopant and having a lesser vertical dimension into the substrate and a greater lateral dimension toward or under the gate structure.

2. The semiconductor device as recited in claim 1 wherein the first source/drain extension implant portion does not extend under a gate electrode portion of the gate structure and wherein the second source/drain extension implant portion does extend under the gate electrode portion of the gate structure.

3. The semiconductor device as recited in claim 1 wherein the dopant has a peak dopant concentration ranging from about 1E19 atoms/cm³ to about 1E22 atoms/cm³ and the different dopant has a peak dopant concentration ranging from about 5E17 atoms/cm³ to about 2E22 atoms/cm³.

4. The semiconductor device as recited in claim 1 wherein the dopant has a diffusivity and the different dopant has a greater diffusivity.

5. The semiconductor device as recited in claim 4 wherein the dopant is arsenic and the different dopant is phosphorous.

6. The semiconductor device as recited in claim 4 wherein the dopant is indium and the different dopant is boron.

7. The semiconductor device as recited in claim 1 wherein the source/drain region further includes a source/drain contact implant located within the substrate.

8. The semiconductor device as recited in claim 7 wherein the source/drain contact implant comprises the dopant or the different dopant.

9. The semiconductor device as recited in claim 8 wherein the source/drain contact implant comprises the dopant having a peak dopant concentration ranging from about 1E19 atoms/cm³ to about 1E22 atoms/cm ³.

10. A method for manufacturing a semiconductor device, comprising:
providing a gate structure over a substrate; and
forming a source/drain region within the substrate and proximate the gate structure, including;
forming a first source/drain extension implant portion within the substrate, the first source/drain extension implant portion comprising a dopant and having a vertical dimension into the substrate and a lateral dimension toward or under the gate structure; and
forming a second source/drain extension implant portion within the substrate, the second source/drain extension implant portion comprising a different dopant and having a lesser vertical dimension into the substrate and a greater lateral dimension toward or under the gate structure.

11. The method as recited in claim 10 wherein the first source/drain extension implant portion does not extend under a gate electrode portion of the gate structure and wherein the second source/drain extension implant portion does extend under the gate electrode portion of the gate structure.

12. The method as recited in claim 10 wherein the dopant has a diffusivity and the different dopant has a greater diffusivity.

13. The method as recited in claim 12 wherein the dopant is arsenic and the different dopant is phosphorous.

14. The method as recited in claim 12 wherein the dopant is indium and the different dopant is boron.

15. The method as recited in claim 10 wherein forming the first source/drain extension implant portion within the substrate includes implanting the first source/drain extension implant portion into the substrate using a dose of the dopant, and wherein forming the second source/drain extension implant portion within the substrate includes implanting the second source/drain extension implant portion into the substrate using a lesser dose of the different dopant.

16. The method as recited in claim 15 wherein the dose ranges from about 1E14 atoms/cm² to about 5E15 atoms/cm² and the lesser dose ranges from about 1E12 atoms/cm² to about 2E15 atoms/cm².

17. The method as recited in claim 10 wherein forming the second source/drain extension implant portion includes annealing the second source/drain implant portion to cause the second source/drain extension implant portion to have the greater lateral dimension.

18. The method as recited in claim 10 wherein forming the source/drain region further includes forming a source/drain contact implant within the substrate.

19. The method as recited in claim 18 wherein the source/drain contact implant comprises the dopant or the different dopant.

20. An integrated circuit, comprising:
semiconductor devices located over or in a substrate, the semiconductor devices including; and
a gate structure located over the substrate; and
a source/drain region located within the substrate and proximate the gate structure, the source/drain region including;
a first source/drain extension implant portion located within the substrate, the first source/drain extension implant portion comprising a dopant and having a vertical dimension into the substrate and a lateral dimension toward or under the gate structure; and
a second source/drain extension implant portion located within the substrate, the second source/drain extension implant portion comprising a different dopant and having a lesser vertical dimension into the substrate and a greater lateral dimension toward or under the gate structure;
dielectric layers located over the semiconductor devices, the dielectric layers having interconnects therein for forming an operational integrated circuit.
